(19) United States
(12) Patent Application Publication
(10) Pub. No.: US 2004/0207293 A1
(43) Pub. Date: Oct. 21, 2004

(54) Telescoping piezoelectric actuator

(76) Inventor: Charles Erklin Seeley, Niskayuna, NY (US)

Correspondence Address: Paul J. Esatto, Jr., Scully, Scott, Murphy & Presser, 400 Garden City Plaza, Garden City, NY, 11530, US

(21) Appl. No.: 10/417,736

(22) Filed: Apr. 17, 2003

(51) Int. Cl. H01L 41/08

(52) U.S. Cl. 310/328

(57) ABSTRACT

A telescoping piezoelectric stack actuator, comprising a first expandable piezoelectric stack systems, a first sleeve supported by the first piezoelectric stack system for upward movement with said stack system, and a second, expandable piezoelectric stack system supported by said first sleeve for upward movement therewith. Preferably, the actuator further comprises a second sleeve supported by the second piezoelectric stack system for upward movement with said second stack system as the second stack system expands, and a third, expandable piezoelectric stack system supported by said second sleeve for upward movement therewith.

### BACKGROUND OF THE INVENTION

1. Field of the Invention

This invention generally relates to piezoelectric actuators. More specifically, the invention relates to a multi-stage, expandable piezoelectric actuator.

2. Background Art

Piezoelectric materials are frequently used as sensors and actuators. This is due to the electromechanical coupling present in the material.- For instance, a piezo electric actuator produces a force and displacement resulting from an applied electric field. Piezoelectric stack actuators are comprised of several layers of piezoelectric wafers. An electric field is applied to these actuators in the thickness direction, and the resulting force and displacement are also in the thickness direction. Actuators of this type provide sufficient force at the expense of displacement for many applications.

There are some situations in which piezoelectric actuators have, heretofore, not been well suited. In particular, piezoelectric actuators are not well suited for applying a large displacement in very small spaces. In these situations, the height, width and length of the space that the actuator can occupy is a- significant limitation. Force and displacement requirements, given the limited space for the actuator, cannot be met with conventional piezoelectric actuators.

Several types of materials and actuators are currently available to provide actuation in a limited space. These materials include piezoelectric, magnetostrictive, shape memory alloy, and common conducting materials such as steel or iron. Linear and rotary actuators using these materials are available. There are some demanding applications, however, where none of the known actuators are able to meet the necessary requirements. Obtaining sufficient displacement is particularly difficult.

### SUMMARY OF THE INVENTION

An object of this invention is to provide an improved piezoelectric actutator.

Another object of the invention is to provide a piezoelectric actuator with a unique telescoping mechanism.

A further object of the present invention is to provide a piezoelectric actuator with a telescoping mechanism that allows the actuator to provide significant displacement in a very small area.

Another object of the invention is to provide a piezoelectric actuator with a mechanism that allows the actuator to provide significantly more displacement, compared to conventions piezoelectric stack actuators, without a trade-off in force.

These and other objects are attained with a telescoping piezoelectric stack actuator, comprising a first expandable piezoelectric stack system, a first sleeve supported by the first piezoelectric stack system for upward movement with said stack system, and a second, expandable piezoelectric stack system supported by said first sleeve for upward movement therewith. Preferably, the stack actuator further comprises a second sleeve supported by the second piezoelectric stack for upward movement with said second stack as the second stack expands, and a third, expandable piezoelectric stack system supported by said second sleeve for upward movement therewith.

Further benefits and advantages of the invention will become apparent from a consideration of the following detailed description, given with reference to the accompanying drawings, which specify and show preferred embodiments of the invention.

### BRIEF DESCRIPTION OF THE DRAWINGS

FIG. 1 illustrates a piezoelectric wafer.

FIGS. 2 and 3 show a conventional piezoelectric stack actuator.

FIGS. 4 and 5 show a piezoelectric stack actuator embodying this invention.

FIG. 6 shows the elements of the stack actuator of FIG. 4

FIG. 7 is an enlarged view of one of the sleeves of the stack actuator of FIGS. 4 and 5.

FIG. 8 is a cross-sectional view of the stack actuator of FIG. 4 and 5.

FIG. 9 is a top view of an alternate actuator embodying this invention.

FIG. 10 schematically illustrates an apparatus that may be used to measure the displacement of piezo actuators.

### DETAILED DESCRIPTION OF THE PREFERRED EMBODIMENTS

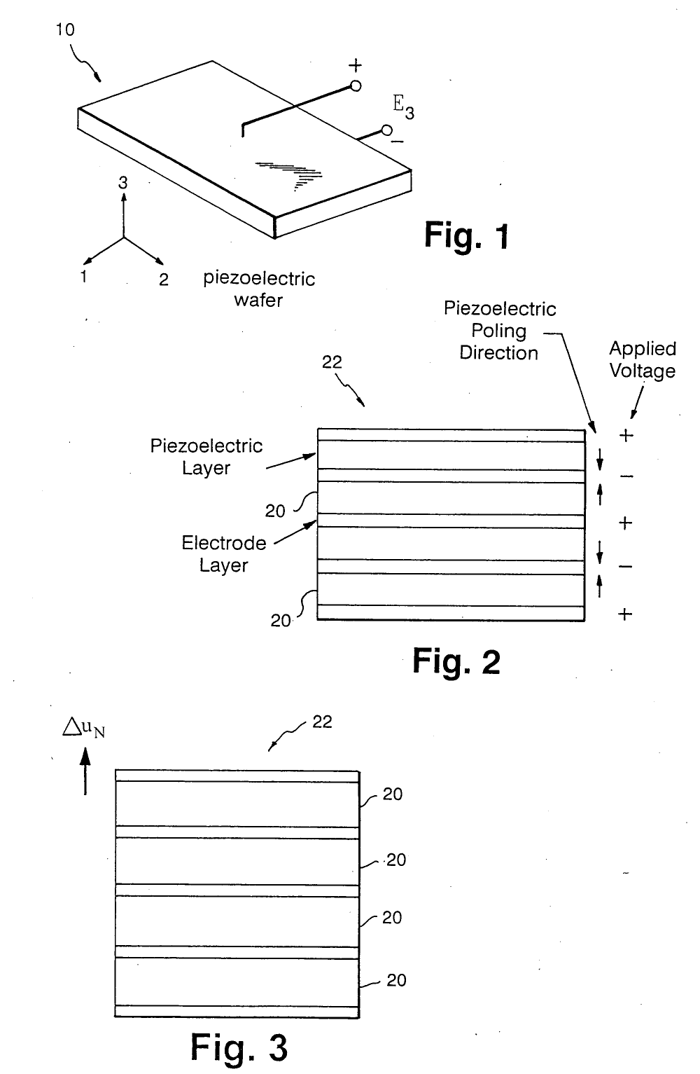

Piezoelectric materials exhibit electromechanical coupling. With reference to FIG. 1, which shows piezoelectric material 10, an applied electric field E₃, through the thickness direction (3), causes the piezoelectric wafer to grow in all directions including in-plane transverse (1) and longitudinal (2). Piezoceramic and piezopolymeric materials grow in the thickness direction at a faster rate than either the transverse or longitudinal directions. Typically, the force generated by a piezoelectric wafer is large, but the displacement is very small. These properties of piezoelectric materials are well known.

As illustrated in FIGS. 2 and 3, the displacement characteristics of piezoelectric materials can be amplified by stacking multiple (N) units 20 in series, as shown at 22. Care must be taken to orient the poling direction of the piezoelectric wafers and the applied electric field correctly. This configuration of piezoelectric materials is well known and commercial piezoelectric stack actuators are available. However, these stack actuators are still limited in their displacement capabilities.

The displacement characteristics of one and multiple wafers stacked in series are given more specifically below.

Displacement of 1 wafer:

Δu₁=t×d₃₁×E₃, where

t—piezoelectric thickness

d₃₁—piezoelectric coefficient

E₃—electric field

Displacement of N wafers:

Δu_{N}=N×Δu₁

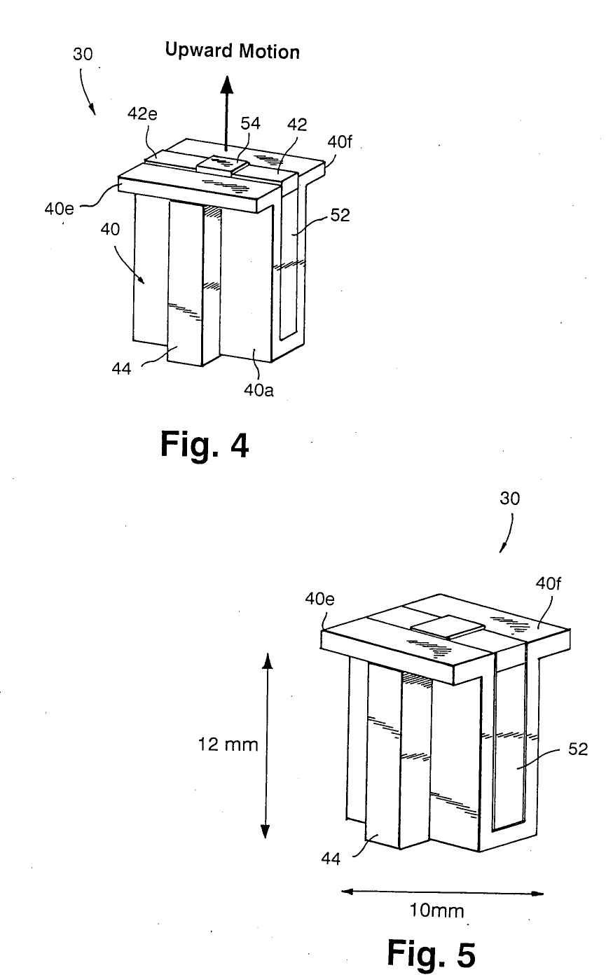

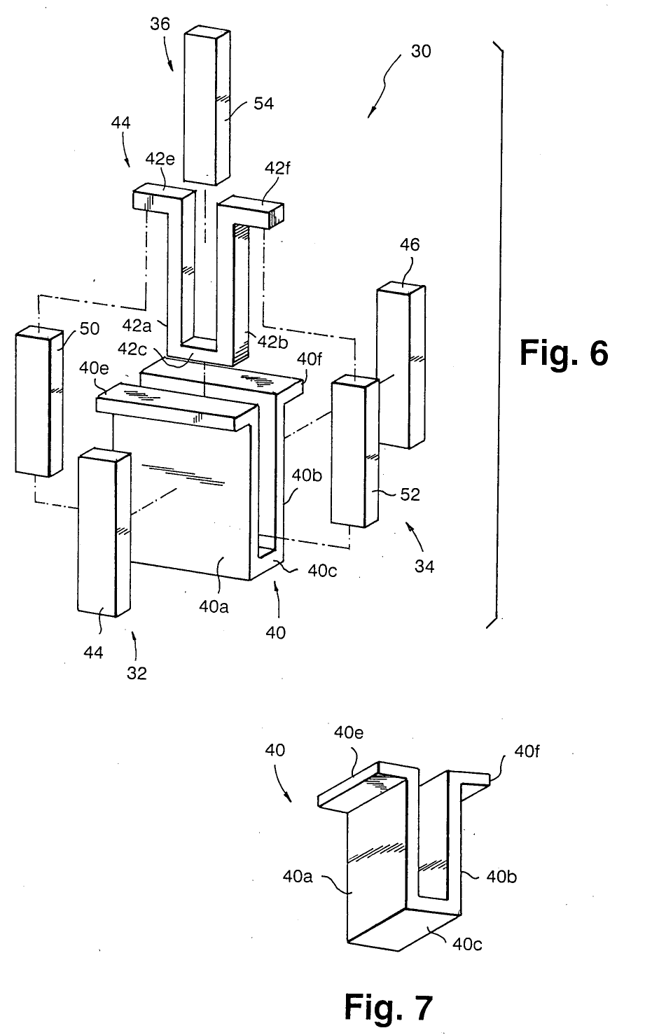

The present invention provides a telescoping design that allows the displacement to be amplified significantly. With reference to FIGS. 4-7, the actuator 30 comprises first, second and third stack systems 32, 34 and 36, and first and second sleeves 40 and 42. Each stack system, it may be noted, is comprised of one or more individual stacks. For example, stack system 32 is comprised of stacks 44 and 46, system 34 is comprised of stacks 50 and 52, and stack system 36 is comprised of stack 54. Each of the stacks is comprised of a multitude of individual piezoelectric layers or wafers mounted one on top of another.

Sleeve 40 has an elongated U-shape, and includes side members 40a and 40b and base member 40c, and the sleeve forms an interior. The sleeve 40 also includes a pair of top flanges 40e and 40f, with these flanges extending outward from the tops of side members 40a and 40b respectively. Sleeve 42, likewise, has an elongated U-shape, and includes side members 42a and 42b and base member 42c, and this sleeve forms an interior. The sleeve 42 also includes a pair of top flanges 42e and 42f, with these flanges extending outward from the tops of side members 42a and 42b respectively.

In actuator 30, stacks 44 and 46 are positioned outside of and on opposite sides of sleeve 40, with the tops of stacks 44 and 46 engaging flange s,40e and 40f. In this way, as stacks 44 and 46 expand, they push flanges 40e and 40f, and the whole sleeve 40, upwards.

Sleeve 42 is disposed inside sleeve 40, between side members 40a and 40b, and preferably the sleeve 42 rests on base member 40c. Stacks 50 and 52 are also disposed inside sleeve 42, between side members 40a and 40b and on opposite sides of sleeve 40. Also, the tops of stacks 50 and 52 engage flanges 42e and 42f so that, as stacks 50 and 52 expand, they push flanges 42e and 42f, and the entire sleeve 42, upwards.

Stack 54 is positioned inside sleeve 42, between side members 42a and 42b, and preferably the stack 54 rests on base member 42c, and stack 54 moves with sleeve 42 as that sleeve moves upward.

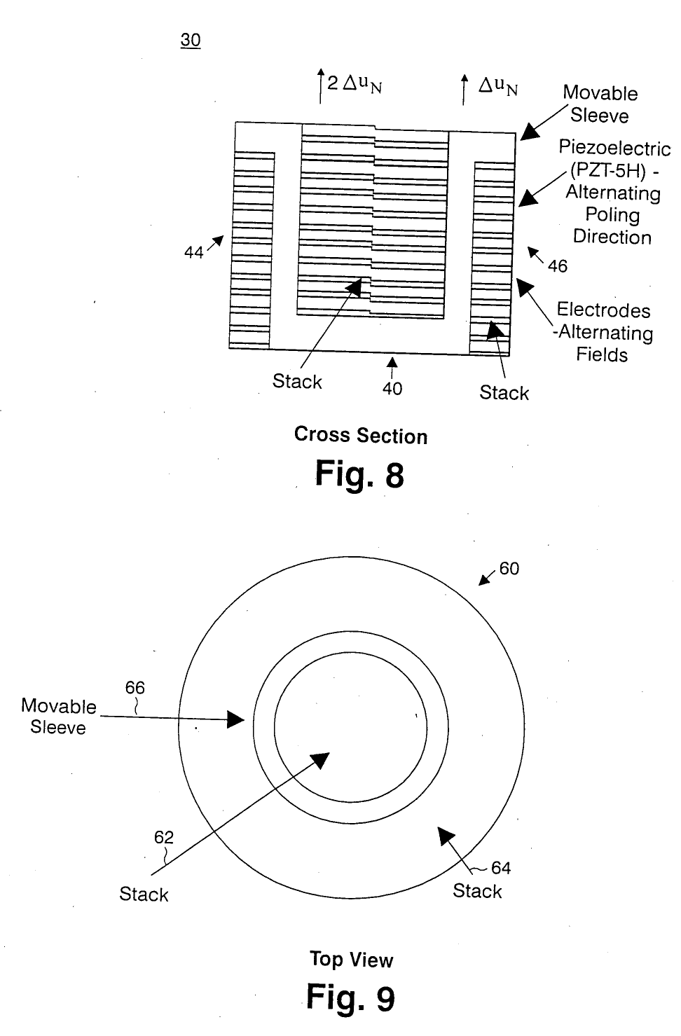

With reference to FIG. 8, the telescoping design of the new actuator 30 allows the displacement to be amplified significantly. Stacks 44 and 46 push up on the sleeve 40 with a displacement of Δu_{N}. Stacks 50 and 52 also push up with a displacement of Δu_{N}. Due to the motion of the sleeve 40 connecting the stacks 44, 46, 50 and 52, the total displacement is 2Δu_{N}. Additional sleeves and stacks can be added to further increase the displacement.

Also, it may be noted that actuators embodying this invention may have specific shapes and sizes. For instance, the actuator may have a square or rectangular shape. Alternatively, as another example, illustrated in FIG. 9, the actuator may have a round or circular shape. In this embodiment, expandable stacks 62 and 64 may have circular shapes, and the movable sleeves, one of which is shown at 66, may also have circular shapes.

In order to demonstrate the advantages of this invention, the displacement obtained with an actuator embodying the invention was compared to the displacement obtained with a prior art single stack piezo actuator.

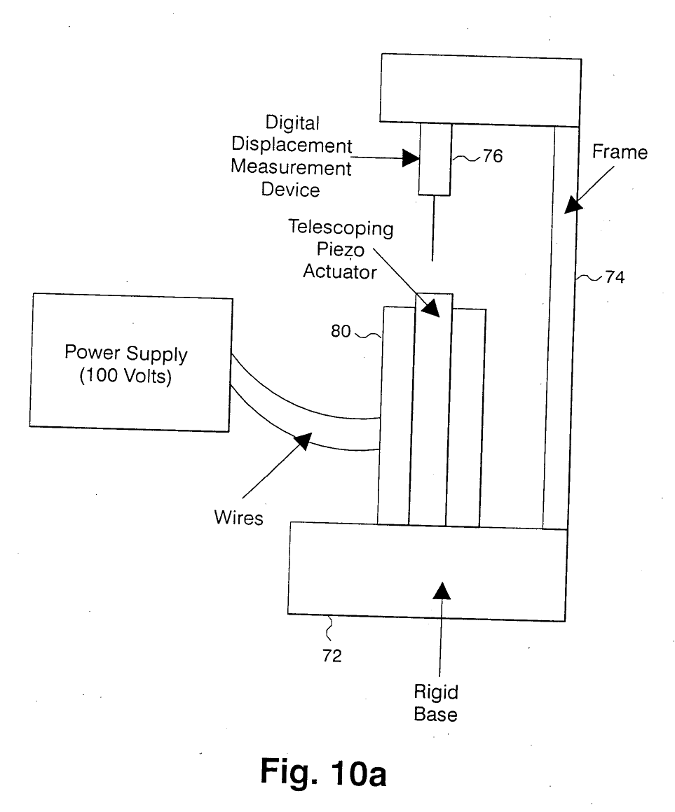

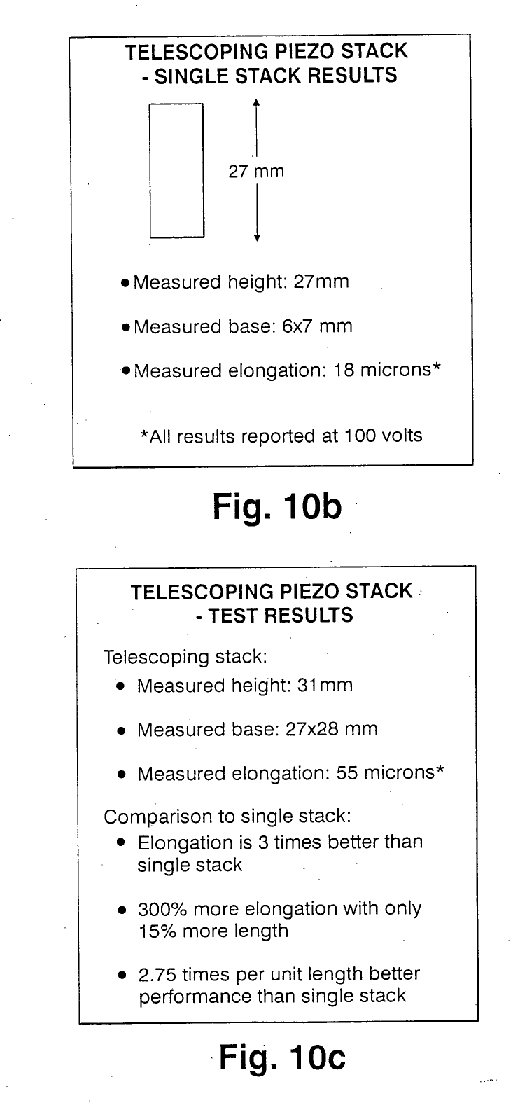

FIG. 10 schematically illustrates an apparatus 70 that was used to measure these displacements; and apparatus 70, generally, comprises a rigid base 72, a frame 74 and a suitable displacement measurement device 76. In use, an actuator, such as actuator 80, is placed on base 72, directly below measurement device 76, an electric voltage is applied to the actuator to expand that actuator, and the extent of this expansion, or displacement, is measured by device 76. As will be understood by those of ordinary skill in the art, any other suitable apparatus may be used to measure the displacement of the actuator.

To obtain a basis for comparison, the displacement of a single stack actuator, represented at 82 in FIG. 10, was measured. This actuator 82 had a height of 27 mm and a base of 6 mm by 7 mm. 100 Volts was applied to the actuator 82, after being mounted on apparatus base 72, and the measured elongation was 18 microns.

The displacement of actuator 80, embodying this invention, was also measured using apparatus 70. Actuator 80 had a height of 31 mm and a base of 27 mm by 28 mm. The actuator 80 was placed on apparatus base 72 and 100 Volts was applied to the actuator, and the actuator elongation was 58 microns. This elongation of the actuator 80 of this invention was three times better than that of the single stack actuator 82. Thus, 300% elongation was obtained with only a 15% increase in the actuator length. A 2.75 times, per unit length, improvement in performance was obtained compared to the single stack actuator.

While it is apparent that the invention herein disclosed is well calculated to fulfill the objects stated above, it will be appreciated that numerous modifications and embodiments may be devised by those skilled in the art, and it is intended that the appended claims cover all such modifications and embodiments as fall within the true spirit and scope of the present invention.

1. A telescoping piezoelectric stack actuator, comprising:
a first expandable piezoelectric stack system;
a first sleeve supported by the first piezoelectric stack system for upward movement with said first stack system as the first stack system expands; and
a second, expandable piezoelectric stack system supported by said first sleeve for upward movement therewith.

2. A telescoping piezoelectric stack actuator according to claim 1, further comprising:
a second sleeve supported by the second piezoelectric stack system for upward movement with said second stack system as the second stack system expands; and
a third, expandable piezoelectric stack system supported by said second sleeve for upward movement therewith.

3. A telescoping piezoelectric stack actuator according to claim 1, wherein:
the first piezoelectric stack system includes first and second, spaced apart, expandable stacks of piezoelectric elements; and
the first sleeve extends between and is supported by the first and second stacks for upward movement therewith.

4. A telescoping piezoelectric stack actuator according to claim 2, wherein:
the first sleeve includes
i) a pair of spaced apart side wall members extending between the first and second stacks, and
ii) a base member connected to and extending between said side wall members; and
the second piezoelectric stack system is supported by the base member of the first sleeve.

5. A telescoping piezoelectric stack actuator according to claim 4, wherein:
the first sleeve further includes a pair of lateral flanges;
each of the flanges is connected to and extends outward from a respective one of the side wall members; and
each of the first and second expandable stacks engage and supports a respective one of said flanges.

6. A telescoping piezoelectric stack actuator according to claim 4, wherein:
each of the first and second expandable stacks includes a top surface; and
each of the flanges is supported on the top surface of a respective one of the first and second stacks.

7. A telescoping piezoelectric stack actuator according to claim 2, wherein:
the second piezoelectric stack system includes third and fourth, spaced apart, expandable stacks of piezoelectric elements, each of the third and fourth stacks being supported by the first sleeve for upward movement therewith; and
the second sleeve extends between and is supported by the third and fourth stacks for upward movement therewith as the third and fourth stacks expand.

8. A telescoping piezoelectric stack actuator according to claim 7, wherein:
the second sleeve includes
iii) a pair of spaced apart side wall members extending between the third and fourth stacks, and
iv) a base member connected to and extending between said side wall members; and
the third, expandable piezoelectric stack system is supported by the base member of the second sleeve.

9. A telescoping piezoelectric stack actuator according to claim 8, wherein:
the second sleeve further includes a pair of lateral flanges;
each of the flanges is connected to and extends upward from a respective one of the side walls of the second sleeve; and
each of the third and fourth expandable stacks engage and supports a respective one of said flanges.

10. A method of assembly a piezoelectric stack actuator, comprising:
providing a first sleeve and first and second expandable piezoelectric stack systems;
mounting the first sleeve on the first piezoelectric stack system, wherein the first sleeve moves upward when the first piezoelectric stack system expands; and
placing the second piezoelectric stack system inside the first sleeve.

11. A method according to claim 10, wherein the providing step includes the step of providing a second sleeve and a third, expandable piezoelectric stack system; and the method further comprises the steps of:
mounting the second sleeve on the second piezoelectric stack system, wherein the second sleeve moves upward when the second piezoelectric stack system expands; and
placing the third piezoelectric stack system inside the second sleeve.

12. A method according to claim 10, wherein:
the first piezoelectric stack system includes first and second stacks; and
the mounting step includes the steps of
i) spacing the stacks apart inside the first sleeve, and
ii) mounting the first sleeve on the top of the first and second stacks.

13. A method according to claim 12, wherein:
the first sleeve includes a pair of lateral flanges; and
the step of mounting the first sleeve on top of the first and second stacks includes the step of mounting a respective one of the flanges on top of each stack.

14. A method according to claim 11, wherein:
the second piezoelectric stack system includes third and fourth stacks; and
the step of mounting the second sleeve includes the steps of
i) placing the third and fourth stacks apart inside the second sleeve, and
ii) mounting the second sleeve on the top of the third and fourth stacks.

15. A method according to claim 14, wherein:
the second sleeve includes a pair of lateral flanges; and
the step of mounting the second sleeve includes the step of mounting a respective one of the lateral flanges on top of each of the third and fourth stacks.

16. A method of operating a telescoping piezoelectric stack actuator, said actuator including a first piezoelectric stack system, a first sleeve supported by the first piezoelectric stack system, and a second piezoelectric stack system supported by the first sleeve, the method comprising the steps of:
expanding the first piezoelectric stack system, wherein the first stack system pushes upwards the first sleeve and the second stack system; and
expanding the second stack system upward.

17. A method according to claim 16, wherein:
the actuator further includes a second sleeve supported by the second stack system, and a third piezoelectric stack system supported by the second sleeve; and
the second stack system pushes the second sleeve upwards when the second stack system expands, and further comprising the steps of expanding the third stack system.
